(19) United States
(12) Patent Application Publication
(10) Pub. No.: US 2014/0252491 A1
(43) Pub. Date: Sep. 11, 2014

(54) SEMICONDUCTOR DEVICE AND MANUFACTURING METHOD OF THE SAME

(71) Applicant: KABUSHIKI KAISHA TOSHIBA, Tokyo (JP)

(72) Inventor: Hiroyuki ONODA, Kanagawa (JP)

(73) Assignee: KABUSHIKI KAISHA TOSHIBA, Tokyo (JP)

(21) Appl. No.: 13/786,112

(22) Filed: Mar. 5, 2013

(51) Int. Cl. H01L 27/092; H01L 21/8234

(52) U.S. Cl. CPC H01L 27/092; H01L 21/823437
USPC 257/369; 438/233

(57) ABSTRACT

According to one embodiment, a semiconductor device includes a first epitaxial layer of a first material, a second epitaxial layer of a second material, a conductive material, a third epitaxial layer of the first material and a fourth epitaxial layer of the second material. The first epitaxial layer is formed in the source region and the drain region of a P-MOS transistor. The second epitaxial layer is formed in the source region and the drain region of an n-MOS transistor. The conductive material includes a gate electrode structure. The third epitaxial layer and the fourth epitaxial layer are laminated around the polysilicon.

### FIELD

Embodiments described herein relate a semiconductor device and manufacturing method thereof.

### BACKGROUND

In CMOS semiconductor devices, as a measure against junction leakage, Si is epitaxially grown in the source/drain region of the N-MOS transistor. This is because the junction leakage current is reduced due to an increase in the effective depth of the source/drain region provided by the epitaxial layer, thus, increasing the distance between the silicide and the junction surface. Additionally, in order to improve mobility of the carrier, SiC is embedded into the source/drain region to apply tension stress on the channel part.

Also, in P-MOS transistors, SiGe epitaxial layers are embedded in the source/drain region in order to improve the carrier mobility of the channel by creating compression stress on the channel part.

On the other hand, a structure using polysilicon as the fuse and the resistor element in semiconductor devices is known. Regarding resistors, a set resistance value can be obtained by doping impurities in polysilicon. Regarding fuses, polysilicon may act as a fuse by dissolving silicide formed on polysilicon.

Along with the advancement in miniaturization of LSI, the degradation of the drive current caused by the depletion of the polysilicon gate electrode that constitutes each MOSFET has become a problem. So, technology to circumvent the depletion of electrodes by using metal gate electrodes has been considered. As one structure that uses such a metal gate electrode, a gate-last type metal gate/high-K structure has been proposed. A high-K (high dielectric constant) insulating film can reduce gate leakage current, since a relatively high resistance gate insulating film can be formed.

In a gate-last type metal gate/high-K structure, a source/drain region is first formed under a state in which a dummy gate has been formed. Afterwards, the dummy gate is eliminated, and a high-K insulating film and a metal gate electrode are formed in the area from where the dummy gate was removed. According to this method, the negative effect of heat treatment during the formation of the source/drain region can be prevented from affecting the gate electrode. Polysilicon is generally used as the material for the dummy gate.

In a related gate-last method, the polysilicon of the dummy gate is not removed for use as a resistor element or a fuse, which incorporates additional mask and etch steps with the attendant cost associated therewith.

### DESCRIPTION OF THE DRAWINGS

FIG. 1 is a schematic cross-sectional view that shows an example of a configuration of the semiconductor device of the embodiment.

FIG. 2A is a schematic plan view that shows an example of a resistor that is formed from polysilicon of the semiconductor device of the embodiment, and FIG. 2B is a schematic plan view that shows an example of a fuse that is formed from polysilicon of the semiconductor device of the embodiment.

FIG. 3A through FIG. 3C are schematic cross-section process diagrams that show an example of a manufacturing method for the semiconductor device of the embodiment.

FIG. 4A through FIG. 4C are schematic cross-section process diagrams that show an example of a manufacturing method for the semiconductor device of the embodiment.

FIG. 5A through FIG. 5C are schematic cross-section process diagrams that show an example of a manufacturing method for the semiconductor device of the embodiment.

FIG. 6A and FIG. 6B are schematic cross-section process diagrams that show an example of a contact forming process of the process of the embodiment.

FIG. 7 is a schematic cross-sectional view that shows an example of the configuration of the semiconductor device of the embodiment.

### DETAILED DESCRIPTION

In general, according to one embodiment, a semiconductor device includes both N-MOS and P-MOS devices, an a first epitaxial layer of a first material, a second epitaxial layer of a second material, a conductive material, a third epitaxial layer of the first material and a fourth epitaxial layer of the second material. The first epitaxial layer is formed in the source region and the drain region of a P-MOS transistor. The second epitaxial layer is formed in the source region and the drain region of an n-MOS transistor. The conductive material includes a gate electrode structure. The third epitaxial layer and the fourth epitaxial layer are laminated around the polysilicon.

The embodiments will be further described below with reference to the drawings. In the drawings, the same codes represent the same or similar parts.

### EMBODIMENTS

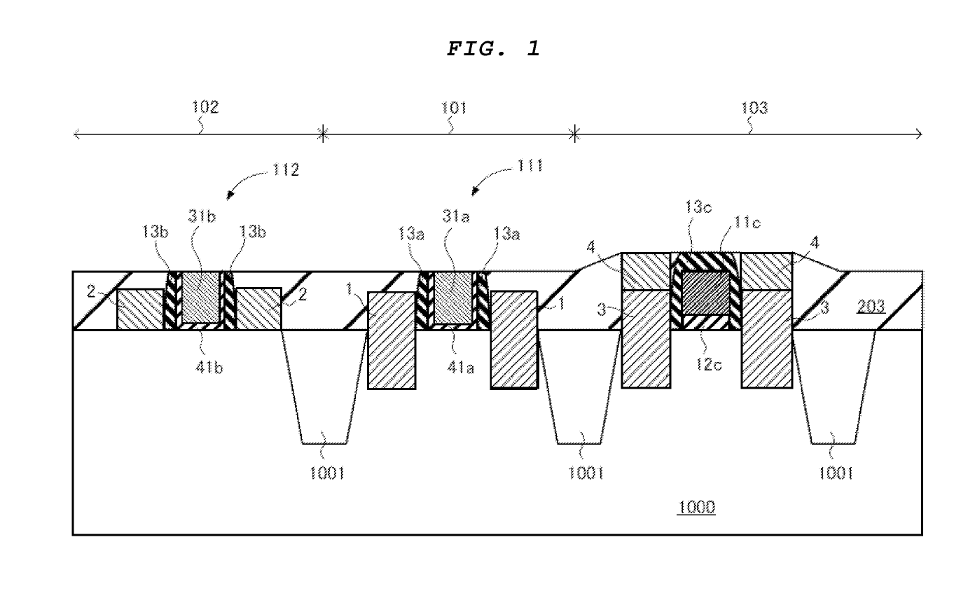

FIG. 1 is a schematic cross-sectional view that shows an example of a configuration of the semiconductor device of the embodiment.

In the semiconductor device of the present embodiment, a region 101 where a P-MOS transistor 111 is formed, a region 102 where an n-MOS transistor 112 is formed, and a region 103 where other devices are formed on a semiconductor substrate 1000 are shown. Each region is separated in an inwardly extending direction of the substrate 1000, or isolated, from other areas of a substrate 1000 by an element separation insulating film (for example, a Shallow Trench Isolation (STI) structure). Additionally, the upper surface of the semiconductor substrate 1000 is covered by an insulating film such as a SiO₂ film 203 as is shown in FIG. 1.

A P-MOS transistor 111 and an N-MOS transistor 112 formed on the substrate 1000 each include a high-K insulating film 41a,41b and a metal gate electrode 31a, 31b formed by the gate-last method.

The P-MOS transistor 111 includes, in the region where the dummy gate was removed, a spacer, which may be an insulating film such as SiN film 13a which bounds the sides of the gate, a high-K gate insulating film 41a formed over the underlying substrate and the inner surfaces of the SiN spacer film 13a, and metal gate electrode 31a formed over the SiN film 13a in the region where the dummy gate was formed. The high-K insulating film 41a on the lower surface of the metal gate electrode 31a becomes the gate insulating film of the P-MOS transistor 111.

The N-MOS transistor 112 has a similarly formed gate structure, wherein high-K gate insulating film 41b coats the interior surface of the SiN spacer film 13b and underlying portion of the substrate bounded thereby, and the metal gate material forms gate 31b over the high-k film 41b. The high-K insulating film 41b on the lower surface of the metal gate electrode 31b becomes the gate insulating film of the N-MOS transistor 112.

Metal materials such as TiN, TaN, TiAl, Ti, and Al, are used for the metal gate electrodes 31a and 31b.

Additionally, insulating materials with a high electric permittivity such as HfSiON, HfO₂, ZrO₂, HfAlO, and AlO₃, are used for the high-K insulating film 41a and 41b.

With the gate-last method, for example, a gate electrode that uses polysilicon, which is a conductive material, is formed as the dummy gate. A metal gate electrode is formed by depositing the metal gate materials in the space created after removing the dummy gate. The material for the gate electrode of the dummy gate is not limited to polysilicon; other conductive materials could be used.

In the present embodiment, the polysilicon of the dummy gate electrode structure 11c, where polysilicon was used as the dummy gate material in the N and P MOS transistor, is not removed and thus is left as a resistor or fuse material in the region 103 where a MOSFET is not formed. That is, in the peripheral region or adjacent region 103 on the substrate to the region where the N and P MOS transistors 111, 112 are formed a gate insulating film 12c and polysilicon layer 11c are formed during the formation of the dummy gate, and remain in place in after removal of the dummy gate and gate insulating film in the transistors 111, 112. The upper surface and the sidewall surface of this polysilicon 11c are covered by an insulating film such as SiN film 13c.

To efficiently form the fuse or resistor in the region 103, the epitaxial layers individually forming the source and the drain of the regions of the P and N MOS transistors are combined in the region of the fuse of resistor to be formed in the dummy gate structure 11c. By forming layer 2 over layer 1 in the dummy gate 11c region, the second epitaxial layer 2 may provide a polish stop layer to protect the dummy gate 11c region, and the fuse or resistor formed therein, during later processing.

Thus, the semiconductor device of the present embodiment includes a first epitaxial layer 1 that is formed in the source region and the drain region of the P-MOS transistor 111 by epitaxially growing SiGe. It includes a second epitaxial layer 2 that is formed in the source region and the drain region of the N-MOS transistor 112 by epitaxially growing Si. The region 103 includes polysilicon 11c with a gate electrode structure, and a third SiGe epitaxial layer 3 formed when the first epitaxial layer 1 is formed, and, a fourth epitaxial Si layer 4 formed when the second, Si epitaxial layer 2, is formed deposited over the third layer 3.

The first epitaxial layer 1 is formed in, and extends from, a recessed surface etched into the surface of the semiconductor substrate 1000. That is, the base of the recess is in a location extended within the surface of the semiconductor substrate 1000. By forming a first epitaxial layer 1 with a lattice constant that is larger than Si, such as SiGe, on the recessed surface, compression stress can be applied to the channel part of the P-MOS transistor 111. The first epitaxial layer 1 extends above the surface of the semiconductor substrate 1000. By doing so, the leakage current of the P-MOS transistor 111 is reduced.

The second, Si epitaxial layer 2, is formed on the surface of the semiconductor substrate 1000. The position of its upper surface is above the semiconductor substrate. The leakage current of the N-MOS transistor 112 is thus reduced.

Meanwhile, for the crystal material for the second epitaxial layer 2, SiC, and the like, with a smaller lattice constant than Si can also be used. In that case, the second epitaxial layer 2 is formed in a recessed in the semiconductor substrate 1000. With this, material and structure tension stress can be applied to the channel part of an N-MOS transistor 112, and the carrier mobility of the channel of the N-MOS transistor 112 can be improved.

The third epitaxial layer 3 is formed simultaneously with the formation of the first epitaxial layer 1. Additionally, the fourth epitaxial layer 4 is formed simultaneously with the formation of the second epitaxial layer 2.

In the manufacturing process of the semiconductor device of the present embodiment, the second epitaxial layer 2 and the fourth epitaxial layer 4 may also be formed after the forming of the first epitaxial layer 1 and the third epitaxial layer 3.

Therefore, the fourth epitaxial layer 4 is formed over the third epitaxial layer 3.

However, the sequence is not limited. That is, the second epitaxial layer 2 and the fourth epitaxial layer 4 can be formed before forming the first epitaxial layer 1 and the third epitaxial layer 3.

In the present embodiment, the position of the upper surface of the fourth epitaxial layer 4 that is laminated on the third epitaxial layer 3 needs to extend above the position of the upper surface of the polysilicon 11c, to form a polishing stop as will be described herein. This third epitaxial layer 3 and fourth epitaxial layer 4 are provided in order to protect the SiN layer 13c on the upper surface of the polysilicon 11c, and thus keep it from being polished during the Chemical Mechanical Polishing (CMP) step used during the removal of the dummy gate structures in the regions 101, 102 by polishing to expose the surface of the polysilicon for later selective etching thereof from the gates, and they the fourth layer serves as a polish stop layer. As mentioned above, in the present embodiment, the polysilicon 11c that is formed as the dummy gate is left in the region 103 when that in the N and/or P MOS transistors is removed, without increasing the manufacturing steps. This polysilicon 11c is used as a resistor or as a fuse.

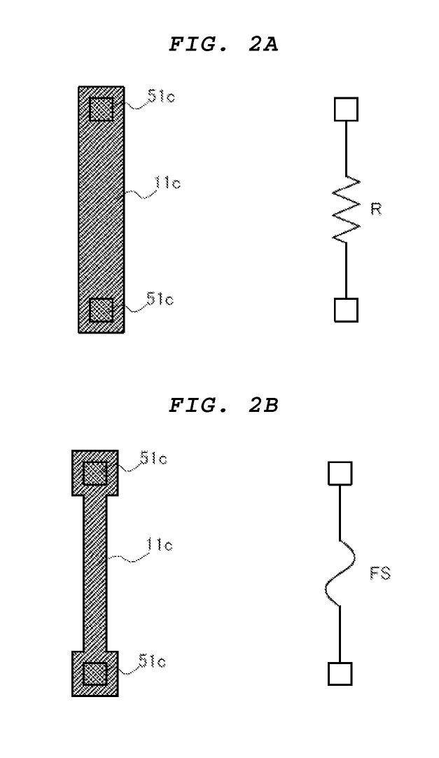

FIG. 2A is a schematic plan view that shows an example where the polysilicon 11c is used as a resistor.

In the example shown in FIG. 2A, two contacts 51c are installed for terminal connection. The polysilicon 11c formed between these two contacts 51c is used as a resistor R.

FIG. 2B is a schematic plan view that shows an example where the polysilicon 11c is used as a fuse.

In the example shown in FIG. 2B, the polysilicon 11c with a narrow width that is formed between two contacts 51c is used as a fuse FS. This fuse FS is, for example, an electrical fuse (e fuse).

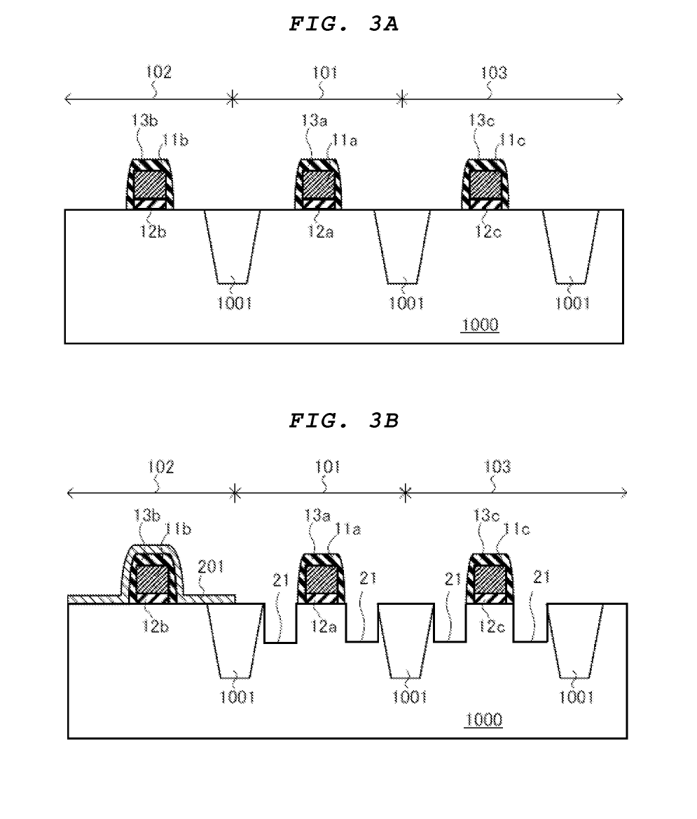

Next, an example of a manufacturing method for the semiconductor device of the present embodiment is described with reference to FIG. 3A through FIG. 5C.

As shown in FIG. 3A, in the manufacturing method of the present embodiment, the semiconductor substrate 1000 that includes the region 101 where a P-MOS transistor is formed, and the region 102 where an N-MOS transistor is formed, and the region 103 for the others is prepared. Each region is separated or isolated by an STI structure 1001.

In the region 101, a gate insulating film 12a and polysilicon 11a that include a gate electrode structure are formed. The upper surface and side surface of the polysilicon 11a are covered by a SiN film 13a.

In the region 102, a gate insulating film 12b and polysilicon 11b that include a gate electrode structure are formed. The upper surface and side surface of the polysilicon 11b are covered by a SiN film 13b.

In the region 103, a gate insulating film 12c and the polysilicon 11c that include a gate electrode structure are formed. The upper surface and side surface of the polysilicon 11c are covered by a SiN film 13c.

As shown in FIG. 3B, the surface of the semiconductor substrate 1000 of both sides of the polysilicon 11a in the region 101, and both sides of the polysilicon 11c in the region 103 are recessed. With this recess, a recessed surface 21 is formed. A mask 201 protects the region between the SiN film 13b and adjacent STI structure from being etched and thus no recess is formed in region 102. As shown in FIG. 3C, a SiGe crystal is epitaxially grown in each recessed surface 21 in the region 101 and the region 103. At this time, the region 102 is covered by the mask 201, and is protected from the epitaxial growth treatment. For the mask 201, SiN and SiO₂ and the like are used.

With the epitaxial growth of this SiGe, a first epitaxial layer 1 is formed around the SiN film 13a and polysilicon dummy gate 11a in region 101 and a third epitaxial layer 3 is formed around the SiN film 13c and dummy gate material polysilicon 11c in the region 103.

The mask 201 is removed after the forming of the first epitaxial layer 1 and the third epitaxial layer 3.

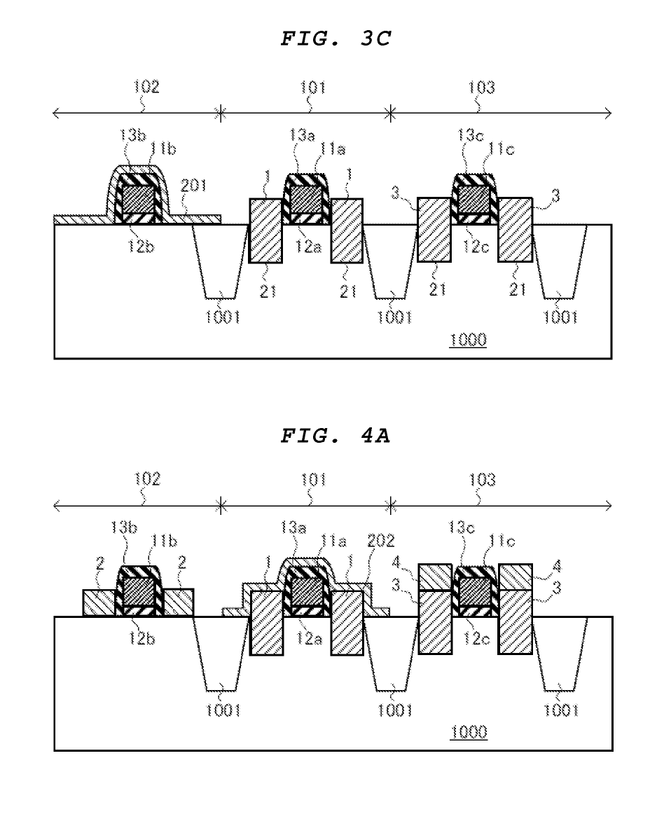

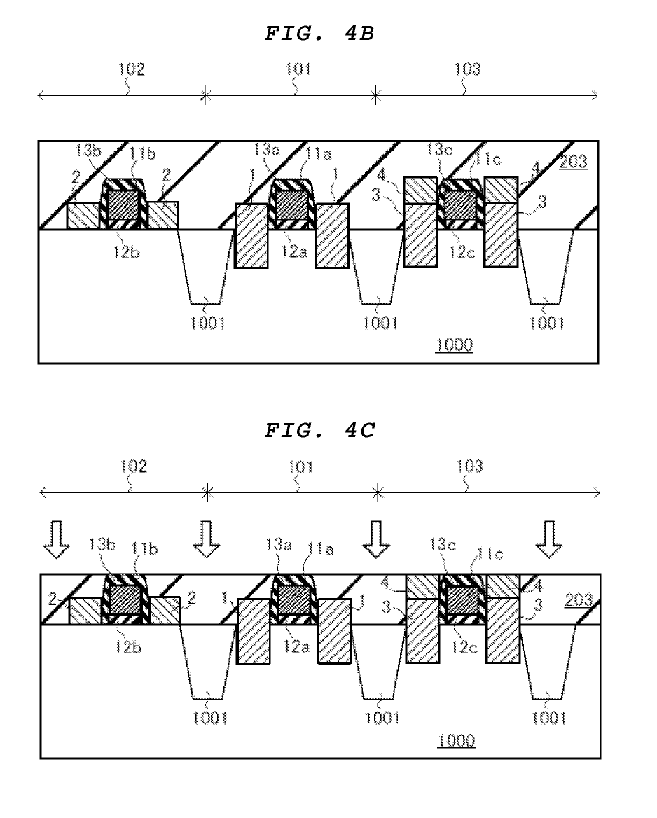

As shown in FIG. 4A, the structure in region 101 is masked with mask 202, such as a SiN or SiO₂ material employing epitaxial growth of Si, a second epitaxial layer 2 is formed around the SiN film 13b and polysilicon dummy gate 11b in region 102 and a fourth epitaxial layer 4 is formed on the epitaxial layer 3 of the region 103.

The fourth epitaxial layer 4 is formed in a position extending further from substrate 1000 than does the position of the upper surface of the polysilicon 11c.

The mask 202 is then removed after forming the second epitaxial layer 2 and the fourth epitaxial layer 4.

As shown in FIG. 4B, the SiO₂ film 203 is formed on the entire upper surface of the semiconductor substrate 1000.

Next, a first polishing step of the entire upper surface of the semiconductor substrate 1000 is carried out by CMP. The slurry used here is a polishing material with a high polishing selectivity of SiO₂ with respect to SiN.

As shown in FIG. 4C, since a slurry with a high polishing selectivity of SiO₂ with respect to SiN is used, polishing of the SiO₂ insulating film 203 is carried out until SiN insulating film 13a, 13b, and 13c are exposed.

When the SiN film 13a, 13b, and 13c are exposed, the slurry is altered. After alteration, a slurry with a high polishing selectivity of SiN with respect to Si is used. With CMP that uses this slurry, the second polishing step of the entire upper surface of the semiconductor substrate 1000 is then carried out.

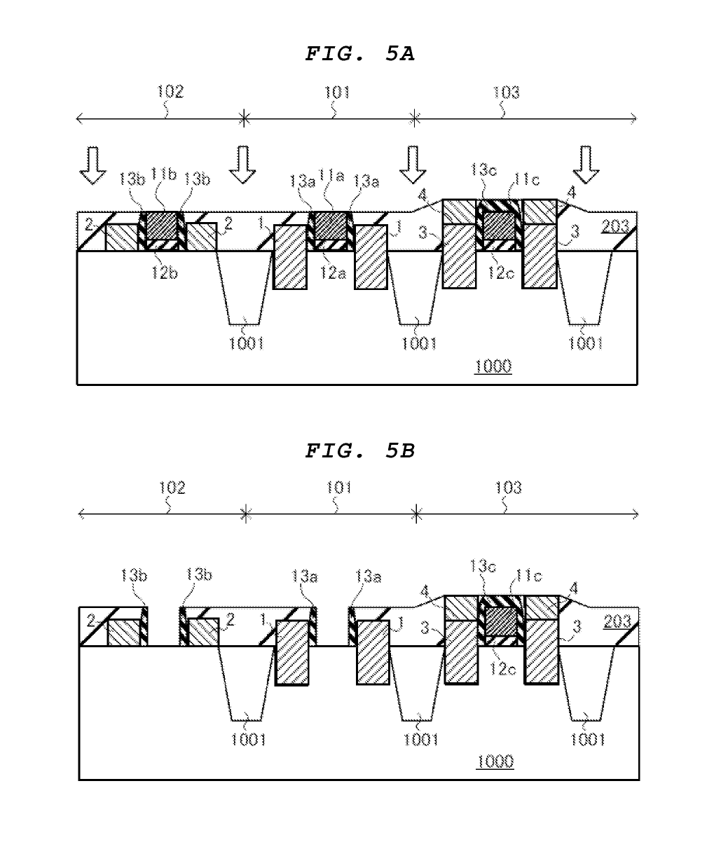

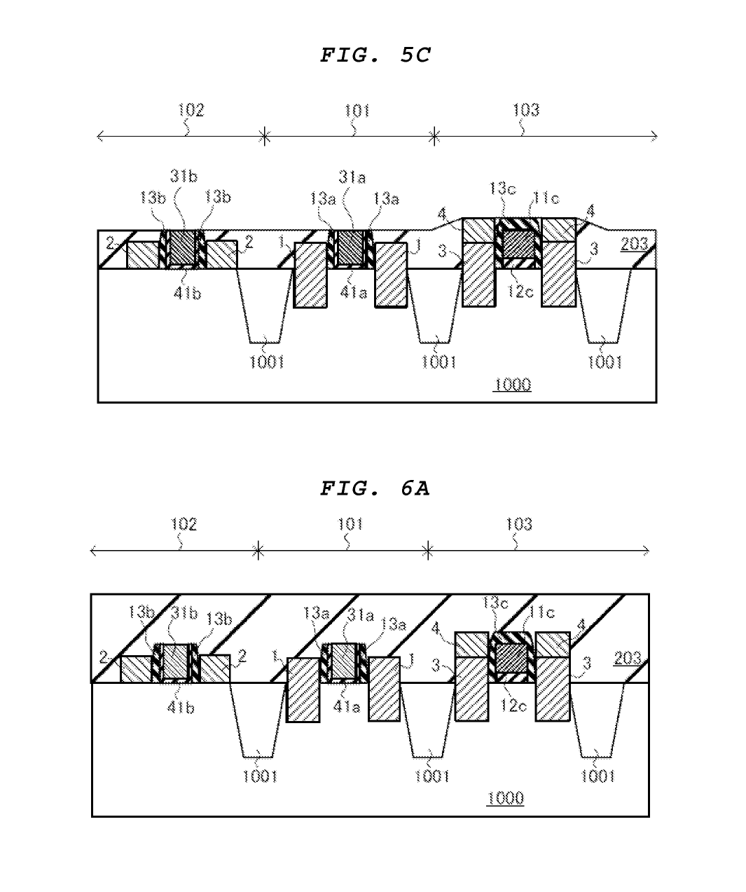

As shown in FIG. 5A, since the slurry with a high polishing selectivity of SiN with respect to Si is used, in the region 101 and the region 102, polishing of the SiN film 13a and 13b is carried out until the upper surface of the polysilicon 11a and 11b are exposed.

On the other hand, in the region 103, since an epitaxial layer 4 made of Si is formed on both sides of the polysilicon 11c, CMP is inhibited by this Si. For this reason, the SiN film 13c on the polysilicon 11c is not polished and remains as is.

As shown in FIG. 5B, the polysilicon 11a in the region 101 and the polysilicon 11b in the region 102 are removed by etching. At this time, since the polysilicon 11c in the region 103 is protected by the SiN insulating film 13c, it will not be removed.

After that, the gate insulating film 12a in the region 101 and the gate insulating film 12b in the region 102 are removed by etching.

As shown in FIG. 5C, the high-K insulating film 41a is formed on the bottom and side surfaces of the gate region after the polysilicon 11a and the gate insulating film 12a in the region 101 are removed, and the metal gate electrode 31a is formed thereover. Likewise, the high-K insulating film 41b is formed on the bottom and side surfaces of the gate region in region 102 after the polysilicon 11b and the gate insulating film 12b in the region 102 are removed, and the metal gate electrode 31b is formed there over.

TiN, TaN, TiAl, Ti, and Al, and the like, may be used for the metal gate electrodes 31a and 31b. Additionally, HfSiON, HfO₂, ZrO₂, HfAlO, and AlO₃, and the like, may be used for the high-K insulating film 41a and 41b.

According to this kind of manufacturing method of the present embodiment, the metal gate electrode 31a and the metal gate electrode 31b can be formed in the region 101 and the region 102 by making the polysilicon the dummy gate, and, the polysilicon 11c with a gate electrode structure can be left to remain in the region 103.

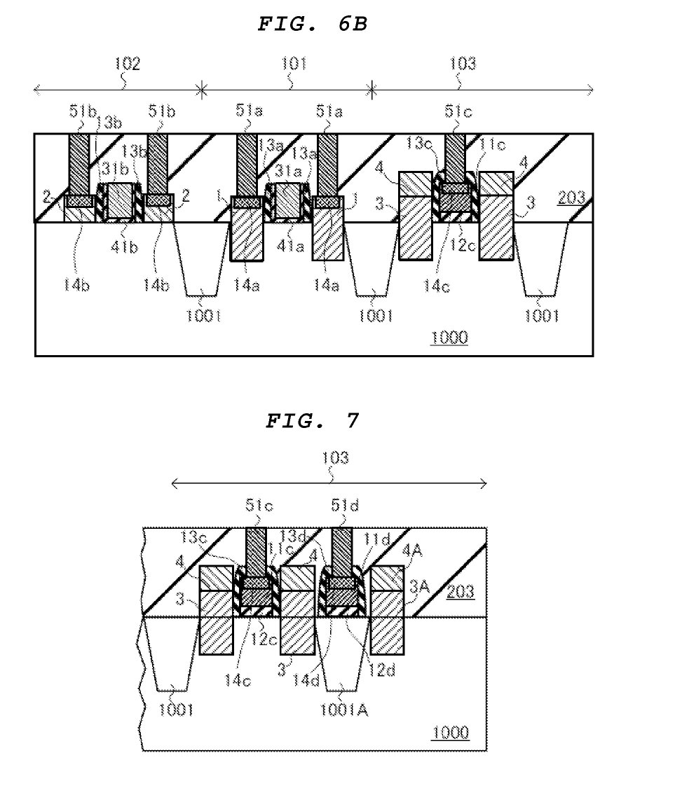

Next, FIG. 6A and FIG. 6B show the contact forming process.

As shown in FIG. 6A, the SiO₂ film 203 is formed on the entire upper surface of the semiconductor substrate 1000.

After that, as shown in FIG. 6B, a contact hole that reaches the first epitaxial layer 1, the second epitaxial layer 2, and the polysilicon layer 11c of the resistor or fuse structure is opened through oxide layer 203, and the upper surfaces of the first epitaxial layer 1, the second epitaxial layer 2, and the polysilicon 11c are silicided to form silicide layers 14a, 14b, and 14c. Thereafter, contacts 51a, 51b, and 51c are connected to the silicide layers 14a, 14b, and 14c are formed.

As shown in FIG. 7, in the region 103, a polysilicon film lid can also be formed on an STI 1001A structure. In this case, an epitaxial layer 3A of SiGe and a Si epitaxial layer 4A are laminated around the polysilicon lid. Also, a silicide layer 14d is formed on the upper surface of the polysilicon lid, to which a contact 51d is connected.

According to the present embodiment such as the above, by deposing a SiGe epitaxial layer and a Si epitaxial layer on the polysilicon with a gate electrode structure, the polysilicon that is otherwise removed as the dummy gate in the process of the gate-last method can be left to remain. With this, a resistor or a fuse can be formed using this polysilicon.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device, comprising:
a first epitaxial layer of a first material that is formed in the source region and the drain region of the P-MOS transistor,
a second epitaxial layer of a second material that is formed in the source region and the drain region of the N-MOS transistor,
an additional conductive material formed in a gate electrode structure, and
a laminate structure wherein a third epitaxial layer of the first material and a fourth epitaxial layer of the second material are laminated around the conductive body.

2. The semiconductor device according to claim 1, wherein
the p-MOS transistor and the n-MOS transistor have gate structures, the gate structures are formed from a gate that includes metal materials and a gate insulating film that is formed on the bottom surface and the side surface of the gate.

3. The semiconductor device according to claim 2, wherein
the conductive body includes a material that differs from the metal materials.

4. The semiconductor device according to claim 3, wherein
the conductive body is polysilicon.

5. The semiconductor device according to claim 1, wherein
the conductive body formed in a gate electrode structure and the laminate structure are on the semiconductor substrate.

6. The semiconductor device according to claim 5, wherein:
the first material is SiGe, and
the position of the bottom surface of the first epitaxial layer is a recessed position extending into the surface of the semiconductor substrate; and the second material is Si, and
the position of the bottom surface of the second epitaxial layer is in the same position as the surface of the semiconductor substrate.

7. The semiconductor device according to claim 1, wherein
the conductive body with a gate electrode structure is on an insulating film, and the laminate structure is on the semiconductor substrate.

8. The semiconductor device according to claim 1, wherein
the position of the upper surface of the laminate structure extends above the position of the upper surface of the conductive body with a gate electrode structure.

9. The semiconductor device according to claim 1, wherein the conductive body forms a resistor or a fuse.

10. A manufacturing method for a semiconductor device having a metal gate and a gate insulating film, the method comprising:
forming a first region where a P-MOS transistor is formed, a second region where an N-MOS transistor is formed, and a third region for others;
forming a conductive body with a gate electrode structure in each of the first region, the second region, and the third region;
covering an upper surface and a side surface of the conductive body with a first insulating film;
forming a first epitaxial layer made from a first material on the side surface of the first insulating film that is formed in the first region, and a third epitaxial layer made from the first material on the side surface of the first insulating film that is formed in the third region;
forming a second epitaxial layer made from a second material on the side surface of the first insulating film that is formed in the second region, and a fourth epitaxial layer made from the second material on the third epitaxial layer of the third region, wherein the fourth epitaxial layer extends to a position higher than the position of an upper surface of the conductive body;
covering an upper surface of the semiconductor substrate with a second insulating film;
polishing with an surface of the second insulating film using a slurry until the first insulating film of the first region and the second region is removed; and
removing the gate electrode structure in the first and second regions and replacing the gate electrode structure with a gate electrode comprising a different material.

11. The manufacturing method according to claim 10, wherein
the first material is SiGe, and
after the surface of the semiconductor substrate is recessed, the first epitaxial layer is formed in that recessed region.

12. The manufacturing method according to claim 11, wherein
the second material is Si, and
the second epitaxial layer is formed on the surface of the semiconductor substrate.

13. The manufacturing method according to claim 11, wherein
the second material is SiC, and
after the surface of the semiconductor substrate is recessed, the second epitaxial layer is formed in that recessed region.

14. The manufacturing method according to claim 10, further comprising:
the upper surface of the conductive body of the third region is made to silicide to form a silicide layer, and
a contact that connects to the silicide layer is formed.

15. The manufacturing method according to claim 14, wherein
a resistor or a fuse is formed using the conductive body of the third region.

16. A semiconductor structure formed on a substrate comprising;
a transistor having a metal gate
an adjacent structure, having a gate structure employing a gate material other than the gate material in the transistor,
an insulating film on the substrate and extending between the transistor and adjacent structure, wherein the thickness of the insulating film is thicker in the area adjacent to the adjacent structure than in the transistor.

17. The semiconductor structure of claim 16, wherein the adjacent structure includes polysilicon which was formed on the substrate in a gate metal gate last process.

18. The semiconductor structure of claim 17, wherein the adjacent structure is a fuse or resistor.

19. The semiconductor device of claim 16, further including a second transistor having a gate,
a first semiconductor film layer material extending around the metal gate and the adjacent structure from a position inwardly of the substrate to a position spaced from the substrate surface; and
a second semiconductor material extending around the gate of the second transistor and also on the first material extending around the adjacent structure.

20. The semiconductor device of claim 19, wherein the polishing properties of the second layer material and the insulating film are different.
